(19) United States
(12) Patent Application Publication
(10) Pub. No.: US 2009/0120488 A1
(43) Pub. Date: May 14, 2009

(54) Luminescent solar concentrator devices

(76) Inventors: Istvan Gorog, Lancaster, PA (US); Robert J. Pressley, San Francisco, CA (US)

Correspondence Address: Robert Charles Hill, 235 Montgomery Street #821, San Francisco, CA, 94104, US

(21) Appl. No.: 12/290,541

(22) Filed: Oct. 31, 2008

Related U.S. Application Data
(60) Provisional application No. 61/002,439, filed on Nov. 9, 2007.

(51) Int. Cl. H01L 31/042

(52) U.S. Cl. 136/247

(57) ABSTRACT

A relatively large field of laminated fluorescent square LSC tiles are interdigitated by long thin bi-facial silicon photovoltaic cells. The laminated fluorescent LSC tiles each comprise a thick clear substrate bonded to a fluorescent dye film with a mirror backing and a protective layer. Incident sunlight is received by the clear substrate's face, and the dye converts that to fluorescent light. The resulting fluorescent light can only escape out the perimeter edges of the clear substrate where the photovoltaic cells are positioned. Each silicon photovoltaic cell receives fluorescent light laterally from the adjacent and opposite edges of the two fluorescent LSC tiles it separates. The collection area of the face of each fluorescent LSC tile is very large compared to the areas of the edges, and so highly concentrated light is provided to relatively small area photovoltaic cells for conversion to electricity.

### RELATED APPLICATIONS

This Application claims benefit of U.S. Provisional Patent Application, Ser. 61/002,439, filed Nov. 6, 2007, and titled, IMPROVED LSC PHOTOVOLTAIC DEVICES.

### FIELD OF THE PRESENT INVENTION

The present invention relates to luminescent solar concentrator photovoltaic cells, and in particular to methods for and devices with reduced silicon areas and reduced fluorescent dye usage.

### BACKGROUND

Fossil fuels as a principal energy source have a number of problems. They are not renewable, and the day will come when supplies dwindle below demand levels. Fossil fuels also contribute to air, land, and water pollution, and expensive and extraordinary measures are needed to control and limit such pollution. Cleaner, renewable energy sources are widely seen as the only long term solutions. Today, they are replacing fossil fuels in ever expanding ways.

The use of fossil fuels to produce electricity can be reduced with solar energy systems. Semiconductor photovoltaic cells can directly convert the photons in strong sunlight into direct current electricity. The stronger the light, and the larger and more numerous the photovoltaic cells, the more electrical power can be produced. Some of the most developed and most widely used photovoltaic technology depends on crystalline silicon wafers for the direct conversion of sunlight into electricity. But such technology is also expensive.

The purchase price of crystalline silicon photovoltaic cells can exceed five dollars per peak watt ($5/W) of output. Even though the capital costs are high, the operational costs are very low. Sunlight is basically free. The most common type of photovoltaic converter uses crystalline silicon. However amorphous silicon, copper indium gallium selenide (CIGS), and cadmium telluride (CdTe), are also being used in various applications.

The solar energy industry is always looking for ways to lower the cost of photovoltaic converters. One well-known approach has been to use concentrators, in which the incident sunlight is concentrated onto the available areas of silicon to make them work harder. Lenses and mirrors have been obvious ways to concentrate sunlight, and used for hundreds of years.

Luminescent solar concentrators (LSC) absorb the incident sunlight with a florescent dye that is doped into a substrate or bonded film. The dye emits florescent light that becomes trapped inside the substrate by total internal reflection (TIR). The florescent light eventually works its way out to the substrate edge, where it can be absorbed by a suitable photovoltaic converter.

There are two significant cost drivers in LSC devices, the costs associated with the fluorescent-dye light conversion, and the costs associated with the silicon photovoltaic conversion. Reducing the costs of either part will reduce the cost of the whole.

### SUMMARY OF THE PRESENT INVENTION

A relatively large field of laminated fluorescent square LSC tiles are interdigitated by long thin bi-facial silicon photovoltaic cells. The laminated fluorescent LSC tiles each comprise a thick clear substrate bonded to a fluorescent dye film with a mirror backing and a protective layer. Incident sunlight is received by the clear substrate's face, and the dye converts that to fluorescent light. The resulting fluorescent light can only escape out the perimeter edges of the clear substrate where the photovoltaic cells are positioned. Each silicon photovoltaic cell receives fluorescent light laterally from the adjacent and opposite edges of the two fluorescent LSC tiles it separates. The collection area of the face of each fluorescent LSC tile is very large compared to the areas of the edges, and so highly concentrated light is provided to relatively small area photovoltaic cells for conversion to electricity.

The above summary of the invention is not intended to represent each disclosed embodiment, or every aspect, of the invention. Other aspects and example embodiments are provided in the figures and the detailed description that follow.

### BRIEF DESCRIPTION OF THE DRAWINGS

The present invention may be more completely understood in consideration of the following detailed description of various embodiments of the invention in connection with the accompanying drawings, in which:

FIGS. 1A and 1B are cross-sectional and perspective views of a single layer luminescent solar concentrator photovoltaic cell embodiment of the present invention;

FIGS. 2A and 2B are cross-sectional and perspective views of a two layer luminescent solar concentrator photovoltaic cell embodiment of the present invention;

FIG. 3 is a cross sectional view diagram showing the construction of an LSC tile in which a substrate is doped with fluorescent dye pigments; and

FIG. 4 is a cross sectional view diagram showing the construction of an LSC tile in which a clear substrate 302 is not doped. A film treated with fluorescent dye is instead bonded to the back of the substrate.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

In the following detailed description of the preferred embodiments, reference is made to the accompanying drawings, which form a part hereof, and within which are shown by way of illustration specific embodiments by which the invention may be practiced. It is to be understood that other embodiments may be utilized and structural changes may be made without departing from the scope of the invention.

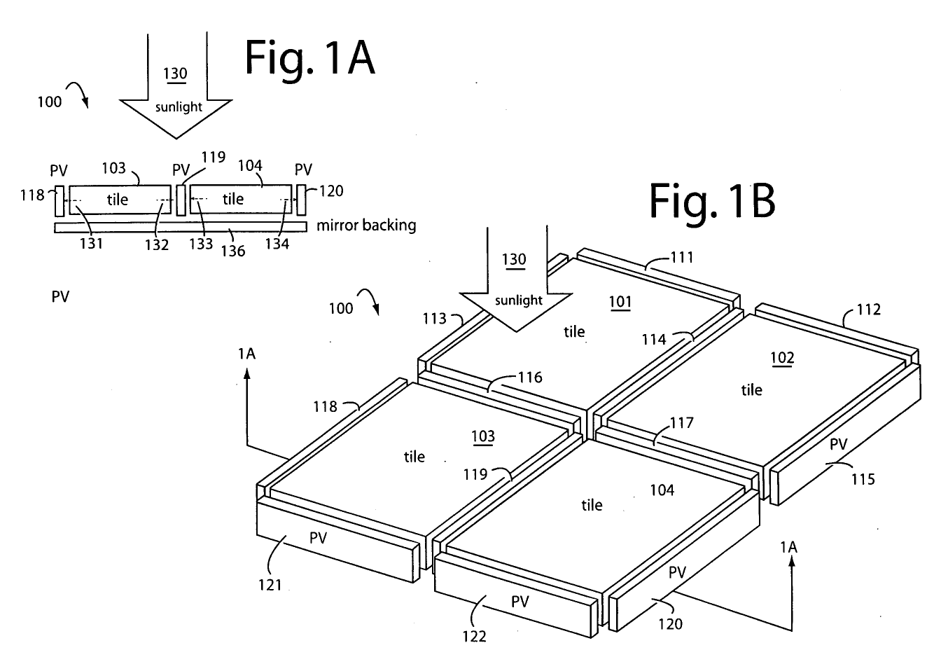

FIGS. 1A and 1B show a luminescent solar concentrator (LSC) photovoltaic (PV) device embodiment of the present invention, that is referred to herein by the general reference numeral 100. Device 100 is fabricated with a number of LSC tiles 101-104 interdigitated and surrounded with thin, long, bi-facial PV cells 111-120. For example, one type of suitable PV cell is commonly called a SLIVER. The several LSC tiles 101-104 are made of an optically clear substrate material like glass or polycarbonate, and either doped with fluorescent dye or bonded to a fluorescent dye film backing. Although four LSC tiles are shown, it should be obvious that any number are possible and practical.

The elements of FIGS. 1A and 1B are shown separated by small gaps merely for purposes of illustration, here and in the other drawings too. Such elements will perform best when in optical contact with one another.

Incident sunlight 130 will excite the fluorescent dye and cause a secondary emission of fluorescent light 131-134 that will become trapped by total internal reflection (TIR) between the faces of the LSC tiles and can only escape out the thin edges where the photovoltaic cells 111-120 are located and facing. The large collection area of the LSC tile faces thus allows a concentration of photon energy that is squeezed down to the small area of one or the other of the two faces of each photovoltaic cell 111-120. The PV cells 111-120 will thereby produce a much greater electrical output than they would if they each had been turned to receive the incident sunlight 130 directly.

A mirror backing 136 may be placed underneath to return any light that leaked through or around the LSC tiles and PV cells. The edges of device 100 are shown here fringed with PV cells, but an alternative embodiment can instead fringe the whole with LSC tiles to drive the outside faces of the outermost PV cells. Any gaps between the components shown here should be minimized and then filled with a clear, index-matching glue or encapsulent.

The particular fluorescent dyes used with the LSC tiles can be advantageously selected according to the particular light frequencies they transmit, absorb, and emit. Various colors and bands have corresponding advantages in different applications. One consideration would be to match the colors the LSC tiles emit to those that the PV cells are most sensitive to. Or, a sort of color detector matrix could be constructed even though the particular colors being sensed in each LSC tile were not the most efficient for adjacent PV cell electrical output.

Fluorescent dyes suitable for plastics include perylene, naphthalimide, courmarin, thioxanthene, anthraquinone, etc.

The mirror backing 136 can be covered with an anti-Stokes coating so that long-wave infrared (IR) radiation passing through the LSC tiles 101-104 will be returned with the help of the mirror as short-wave IR and thus provide useful photon energy to further stimulate the fluorescent dyes. For example, anti-Stokes pigments like Epolin A225 or A274 can be used, as supplied by Epolin, Inc., Newark, N.J. Such mirror backing 136 will be necessary if significant amounts of incident sunlight are able to pass through the LSC tiles.

A typical device 100 can have LSC tiles each only a few centimeters square, up to several meters square. Any number of LSC tiles can be used, with square and hexagon shapes providing the most efficient lateral area coverage. The LSC tile thicknesses can be in the range of 1.0 mm to 10 mm. The PV cells are each sized accordingly, or used in multiples.

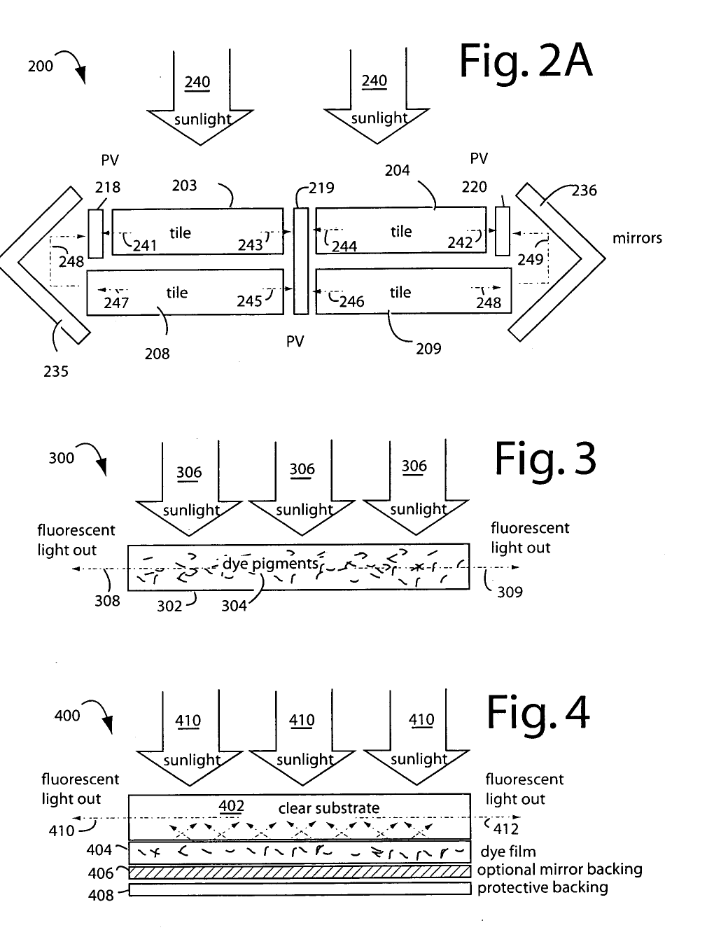

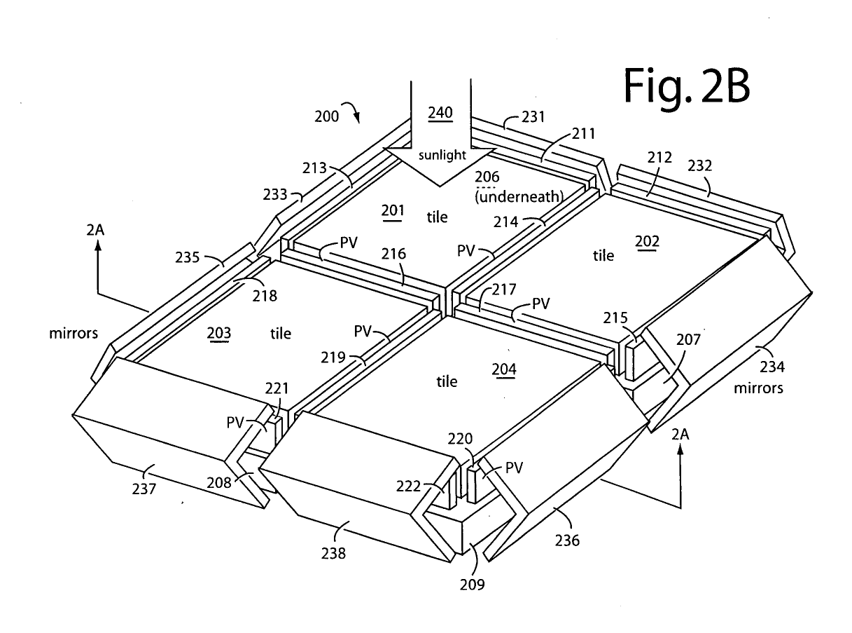

FIGS. 2A and 2B shown a two tile-layer LSC PV device 200. Such would be especially useful where the outside perimeter length was relatively long compared to the length of the section divisions inside the field of LSC tiles. Or, in the case of a single LSC tile with only its outside perimeter edges available to equip with bi-facial PV cells. A top layer of LSC tiles 201-204 overlays a bottom layer of LSC tiles 206-209. But only one layer of PV cells 211-220 is included, and they only interdigitate and surround the top layer of LSC tiles 201-204. A perimeter of reflectors 231-238, or 90-degree prisms is provided to steer the fluorescent light from the bottom layer of LSC tiles up to the outside faces of the perimeter set of PV cells 211, 212, 213, 215, 216, 218, 220, 221, and 222.

In an alternative embodiment of that shown in FIG. 2A, PV cell 219 would not be used, LSC tiles 203 and 204 would be a single piece, as would LSC tiles 208 and 209.

Incident sunlight 240 will excite the fluorescent dye and cause a secondary emission of fluorescent light 241-244 that will become trapped by total internal reflection (TIR) between the faces of the LSC tiles 203-204 and can only escape out the thin edges where the photovoltaic cells 218-220 are located and facing. Any incident sunlight 240 that passes through LSC tiles 203-204 will reach LSC tiles 208-209. Another secondary emission of fluorescent light 245-248 will be trapped by TIR between the faces of the LSC tiles 208-209 and will escape out the thin edges where 90-degree reflectors 235-236 are located and facing. A reflection 248-249 will illuminate the second, outer sides of PV cells 218 and 220.

In an alternative embodiment, the 90-degree reflectors, e.g., 235-236, are implemented with prisms that demonstrate total internal reflections.

In one embodiment, the bottom layer of LSC tiles 206-209 use fluorescent dyes that are sensitive to different wavelengths than those in the top layer of LSC tiles 201-204. In particular, the top layer of LSC tiles 201-204 may be transparent to the wavelengths of light that the bottom layer of LSC tiles 206-209 will absorb. A fuller slice of the spectrum included in incident sunlight can thus be employed and put to useful advantage.

Attention is called to the fact that the perimeter edges of the bottom layer of LSC tiles 206-209 extends out further than does the corresponding edges of the top layer of LSC tiles 201-204. This makes up for the fact that a gap is left between the bottom layer of LSC tiles 206-209 and the reflectors 231-238 by there not being any PV cells there. Inside the field of LSC tiles, the PV cells 214, 216, 217, and 219, could either be extended down, or the bottom layer of LSC tiles 206-209 could instead be one solid sheet spanning the whole width and length.

FIG. 3 provides more detail about the construction of an LSC tile 300 in which a substrate 302 is doped with fluorescent dye pigments 304. When incident sunlight 306 enters through an exposed face of the substrate 302, fluorescent light 308 and 309 will be emitted laterally.

FIG. 4 provides more detail about an alternative construction of an LSC tile 400 in which a clear substrate 302 is not doped, and instead has a film 404 treated with fluorescent dye pigments. A mirror backing 406 and a protective backing 408 can be added in some applications. When incident sunlight 410 enters through an exposed face of the substrate 402, fluorescent light 410 and 412 will be emitted laterally.

In general, the reflective mirrors illustrated here can be disposed on the outside edges of a long 90-degree prism to provide for a more monolithic construction.

While the invention has been described with reference to several particular example embodiments, those skilled in the art will recognize that many changes may be made thereto without departing from the spirit and scope of the invention, which is set forth in the following claims.

1. A luminescent solar concentrator (LSC) photovoltaic (PV) cell, comprising:
a plurality of fluorescent-dye LSC tiles that can receive incident sunlight on one of their faces and convert that to fluorescent light that can only escape out the edges of each LSC tile;
a plurality of bi-facial silicon photovoltaic cells interdigitated between adjacent ones of the plurality of fluorescent-dye LSC tiles and arranged to receive said fluorescent light escaping out the edges of each LSC tile;
wherein, the energy of the incident light is thereby concentrated and substantially increases the electrical output of the photovoltaic cells.

2. The device of claim 1, wherein:
the plurality of fluorescent-dye LSC tiles further comprise laminated fluorescent LSC tiles each including an optically clear substrate bonded to a fluorescent dye film, and a mirror backing with a protective layer.

3. The device of claim 2, further comprising:
a layer of anti-Stokes phosphors positioned in front of said mirror backing;
wherein, long-wave infrared light passing through the clear substrate is up converted to shorter wavelength light that will be absorbed by said fluorescent dye film.

4. The device of claim 1, wherein:
the plurality of fluorescent-dye LSC tiles further comprise an optical substrate doped with a fluorescent dye, and having a mirror backing with a protective coating.

5. The device of claim 4, further comprising:
a layer of anti-Stokes phosphors positioned in front of said mirror backing;
wherein, long-wave infrared light passing through the clear substrate is up converted to shorter wavelength light that will be absorbed by said fluorescent dye in the optical substrate.

6. The device of claim 1, further comprising:
a perimeter of silicon photovoltaic cells ringing the outside boundary of the plurality of fluorescent-dye LSC tiles and arranged to receive any fluorescent light escaping out the edges of each perimeter LSC tile.

7. A luminescent solar concentrator photovoltaic cell, comprising:
a first plurality of fluorescent-dye LSC tiles for receiving incident sunlight on one of its faces, and for converting that to fluorescent light that can only escape out the edges of each LSC tile;
a plurality of bi-facial silicon photovoltaic cells interdigitated between adjacent ones of the first plurality of fluorescent-dye LSC tiles and arranged to receive on a first side said fluorescent light escaping out the edges of each LSC tile in the first plurality of fluorescent-dye LSC tiles;
a second plurality of fluorescent-dye LSC tiles in front of or behind the first plurality of fluorescent-dye LSC tiles, and that can also receive incident sunlight on one of its faces and convert that to fluorescent light that can only escape out the edges of each LSC tile; and
a system of 90-degree reflectors positioned to direct fluorescent light escaping out the edges of each LSC tile in the second plurality of fluorescent-dye LSC tiles to a second side of a photovoltaic cell;
wherein, the energy of the incident light is thereby concentrated and substantially increases the electrical output of the photovoltaic cells.

8. A method of solar energy generation, comprising:
exposing the faces of luminescent solar concentrator (LSC) tiles to receive incident sunlight;
disposing fluorescent dye in said LSC tiles or in a bonded film to convert any sunlight received to fluorescent light; and
positioning bi-facial photovoltaic cells optically between the edges of said LSC tiles to receive said fluorescent light from two opposite directions;
wherein, total internal reflection (TIR) directs said fluorescent light to escape only out the perimeter edges of said LSC tiles where said photovoltaic cells are positioned, and each photovoltaic cell receives fluorescent light laterally from the adjacent and opposite edges of any two fluorescent LSC tiles it separates;
wherein, the collection area of the face of each fluorescent LSC tile is very large compared to the areas of the edges, and so highly concentrated light is provided to relatively small area photovoltaic cells for conversion to electricity.
